(19) United States
(12) Patent Application Publication
(10) Pub. No.: US 2025/0209683 A1
(43) Pub. Date: Jun. 26, 2025

(54) SYSTEM, METHOD, AND COMPUTER PRODUCT FOR PLANNING AND COST ENGINEERING

(71) Applicant: ATC Prince Street LLC, Alexandria, VA (US)

(72) Inventor: Kenneth NASSIF, Alexandria, VA (US)

(73) Assignee: ATC Prince Street LLC, Alexandria, VA (US)

(21) Appl. No.: 18/977,465

(22) Filed: Dec. 11, 2024

Related U.S. Application Data
(60) Provisional application No. 63/613,383, filed on Dec. 21, 2023.

(51) Int. Cl. G06T 11/00; G06F 30/27; G06T 7/62

(52) U.S. Cl. CPC G06T 11/00; G06F 30/27; G06T 7/62

(57) ABSTRACT

A method for planning and cost engineering using an artificial intelligence may be provided. The method may include receiving one or more input documents, the input documents including at least architectural design information. The method may further include converting the input documents into an image file and automatically setting a scale unit based on at least one known measurement of the input documents. The method may further verify the scale unit, automatically measure one or more lengths and one or more areas of the image file based on the architectural design information; and automatically label the one or more measured lengths and one or more measured areas on the image file to generate a labeled image.

### BACKGROUND

In various fields and circumstances, such as architectural analysis, property inspection, real estate acquisition and development, general contracting, improvement cost estimation, etc., it may be desirable to know the interior of a house, office, or other building without having to physically travel to and enter the building. However, it can be difficult to effectively capture, represent and use such building interior information. In addition, while a floor plan of a building may provide some information about layout and other details of a building interior, such use of floor plans has some drawbacks, including that floor plans can be difficult to construct and maintain, to accurately scale and populate with information about room interiors, to visualize and otherwise use, etc.

### SUMMARY

According to one or more embodiments systems and method for planning and cost engineering using artificial intelligence may be provided. In an exemplary embodiment a method for planning and cost engineering using an artificial intelligence may include receiving one or more input documents, the input documents including at least architectural design information. The method may further include converting the input documents into an image file and automatically setting a scale unit based on at least one known measurement of the input documents. The method may further verify the scale unit, automatically measure one or more lengths and one or more areas of the image file based on the architectural design information; and automatically label the one or more measured lengths and one or more measured areas on the image file to generate a labeled image.

### BRIEF DESCRIPTION OF THE FIGURES

Advantages of embodiments of the present invention will be apparent from the following detailed description of the exemplary embodiments. The following detailed description should be considered in conjunction with the accompanying figures in which:

FIG. 1 shows an exemplary input document analysis process.

FIG. 2 shows an exemplary length detection process.

FIG. 3 shows an exemplary walls and area detection process.

FIG. 4 shows an exemplary OCR process.

FIG. 5 shows an exemplary annotation process.

FIG. 6 shows an exemplary annotated floor plan.

### DETAILED DESCRIPTION

Aspects of the invention are disclosed in the following description and related drawings directed to specific embodiments of the invention. Alternate embodiments may be devised without departing from the spirit or the scope of the invention. Additionally, well-known elements of exemplary embodiments of the invention will not be described in detail or will be omitted so as not to obscure the relevant details of the invention. Further, to facilitate an understanding of the description discussion of several terms used herein follows.

As used herein, the word “exemplary” means “serving as an example, instance or illustration.” The embodiments described herein are not limiting, but rather are exemplary only. It should be understood that the described embodiments are not necessarily to be construed as preferred or advantageous over other embodiments. Moreover, the terms “embodiments of the invention”, “embodiments” or “invention” do not require that all embodiments of the invention include the discussed feature, advantage or mode of operation.

Further, some of the embodiments described herein may be described in terms of sequences of actions to be performed by, for example, elements of a computing device. It should be recognized by those skilled in the art that the various sequences of actions described herein can be performed by specific circuits (e.g. application specific integrated circuits (ASICs)) and/or by program instructions executed by at least one processor. Additionally, the sequence of actions described herein can be embodied entirely within any form of computer-readable storage medium such that execution of the sequence of actions enables the at least one processor to perform the functionality described herein. Furthermore, the sequence of actions described herein can be embodied in a combination of hardware and software. Thus, the various aspects of the present invention may be embodied in a number of different forms, all of which have been contemplated to be within the scope of the claimed subject matter. In addition, for each of the embodiments described herein, the corresponding form of any such embodiment may be described herein as, for example, “a computer configured to” perform the described action.

In one or more exemplary embodiment a system, method, and computer product for planning and cost engineering may be provided.

In some embodiments, the system, method, and computer product for planning and cost engineering may be a computer system with one or more inputs and one or more outputs. The inputs may be, for example, PDF files, CAD files, DWG files, Word files, or any other file type known in the art. The outputs may include, for example, cost estimations, and may be in a variety of formats, for example word, excel, PDF, overlaid on the input file and output in the same format, or integrated into an enterprise system. It may be understood as used herein a database may mean local or enterprise level storage or may mean, for example, using cloud storage.

According to one or more embodiments a system may take a variety of drawing files and/or other inputs of, for example, a building floor plan, room plan, 3D image, etc. Various attributes or properties may be considered, even within the same object type, for example length, width, area/shape, rotation angle, mirroring characteristics, etc. The attributes or properties may be with consideration to the whole or to any one or more subcomponents of the whole.

An exemplary approach according to some exemplary embodiments may described. In the exemplary approach the system may take an input, for example a drawing file. Next, AI may detect, from the input, one or more objects and/or sub objects and their characteristics. For example, the one or more objects may be building floorplans, and the one or more sub objects may be room dimensions within the building floorplans. Next, based on the AI detection, the system may calculate and estimate cost properties. The cost estimation may further be performed by AI. The estimation may take into account one or more additional data points, for example user input data, or data from one or more databases. Next estimated results may be output. The estimated results may be generated into any required format, which may be agreed upon, for example, by a customer company.

In some cases an exemplary detection component may include generating, by AI, data. The data may include, for example, room dimensions. The system may then annotate the input data based on the data generation. The system may utilize AI and/or AI training, and may further utilize testing and counting via the AI. In some embodiments the AI and/or ML may process vector images to enable automated building metric assessments. For example by utilizing the vector images as inputs, the AI may perform precise building metric assessments. According to an embodiment, the vector images, with their mathematical representation of shapes and layers, may allow the AI to detect, measure, and classify architectural elements like walls, rooms, and doors with based on annotation and AI training exercises which are further discussed below. Leveraging these properties, the AI may process the vector images by first isolating layers, identifying edges, and recognizing geometric shapes. A scaling mechanism may then pixel-based distances into real-world measurements, ensuring accurate dimensions for cost estimation.

According to a general embodiment a process may include an input being converted into an image file, for example the input may be converted from a PDF into an image file. Data may then be extracted from the converted image and used to generate one or more object and/or sub object properties based on an Artificial intelligence and/or Machine Learning system. The one or more object and/or sub object properties may further be annotated on the image by the AI. In some embodiments the AI algorithm may further be updated, trained, and/or tested based on the generated object and/or sub object properties. After annotation the AI/algorithm may perform an initial count on the annotated image in order to come up with an initial cost estimate. According to an exemplary embodiment the initial cost estimate process may incorporate a cost data library such as a “RS Means Cost Books” to provide up-to-date information on various materials and associated costs. Once objects and sub-objects are identified, measured, and annotated by the AI, the system may calculate an initial cost estimate by associating each annotated component with corresponding material costs from the cost data library (i.e., RS Means Cost Books). The library may include a wide range of material types and may accommodate estimates based on different materials, allowing for flexibility in specifying materials for walls, flooring, insulation, and other structural components.

The cost estimation process may be configured to pull material costs from the RS Means Cost Books or other data libraries, which may be updated in real-time or periodically to reflect market conditions. Users may have the option to override default material selections, entering custom materials or costs if needed. Beyond raw material costs, the system may incorporate additional costs, including labor, taxes, shipping, and handling fees. The AI may apply these extra costs based on standard rates from the library or custom values entered by the user. This comprehensive approach to cost estimation may be understood to provide an accurate view of expenses, aiding in budget planning and cost control for construction projects. Additionally, this process may utilize automated communication, for example automatic calls or emails to suppliers and relevant companies, to request real-time information and vendor quotes to support and augment project cost development. This data may be editable and may be further modified by user inputs.

The system may further check whether additional assistance is required, for example scaling the drawings or other external information. If assistance is needed, then the system may take the input from, for example, a human or external data source, for example the cost library described above. In some embodiments the cost library or other data source may be further augmented via the AI or ML system using tools to search the internet for real time and current material cost estimates, labor estimate & rates, equipment pricing, job board searches, or any other relevant information. After a final cost estimate is determined the system may output the cost estimate and/or annotated image as an output file.

It may be understood that according to different embodiments one or more specific processes may be shown and described.

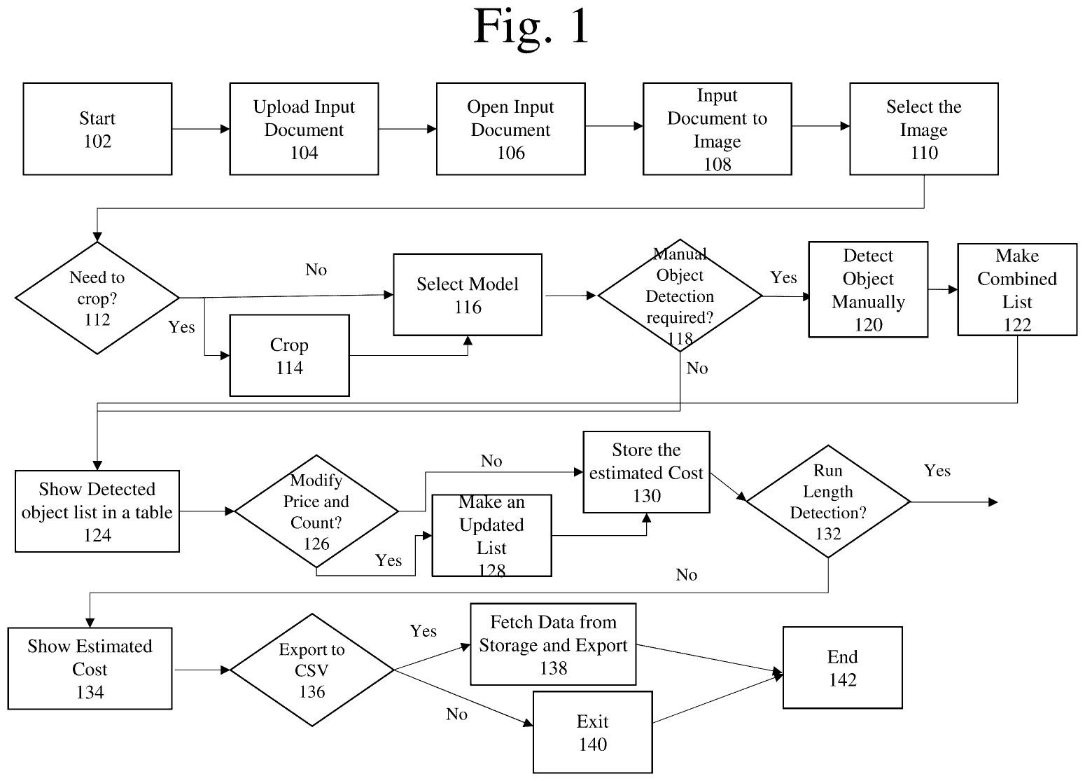

Referring to FIG. 1, an exemplary process for an input document analysis process 100 may be shown and described. In a first step 102 the process may be initialized and started, for example by a processor running instructions off of a memory. In a next step 104 an input document may be uploaded, the input document may be, for example but not limited to, PDF files, CAD files, DWG files, Word files, or any other file type known in the art. In a next step 106 the input document uploaded in step 104 may be opened by the process, and may be converted into an image in step 108. In a next step 110 the image may be selected and may determine whether the image needs to be cropped in step 112. If the image needs to be cropped then in step 114 the image may be cropped. If the image does not need to be cropped the process may skip step 114 and may move to step 116 where a model may be selected. For example, a model may be selected from a set of discipline-specific options tailored to the requirements of the input document. The models may include, but are not limited to, an architectural model for identifying walls, doors, and room layouts; an Electrical Model for locating outlets, wiring pathways, and lighting fixtures; a Plumbing Model for detecting pipes and fixtures; a Fire Safety Model for recognizing sprinklers, alarms, and emergency exits; an HVAC Model for analyzing ducts, vents, and heating/cooling units; and a Structural Model for identifying load-bearing walls, beams, and foundations (etc.). Each model may be pre-trained on data specific to its domain, which may allow the AI to focus on features relevant to the discipline. This flexibility may be understood to ensure accurate detection and analysis, enhancing the system's ability to provide precise cost estimations for various types of construction and renovation projects.

In a next step 118 it may be determined whether object detection is required. In the step 118, the system may assess whether manual object detection is necessary based on specific criteria designed to ensure accuracy. Manual detection may be prompted when the Al's confidence in identifying certain objects falls below a pre-set threshold, indicating a need for human verification. Additionally, ambiguous classifications—such as distinguishing between walls and load-bearing columns in complex layouts—may require manual review. Non-standard or unusual features, such as custom fixtures or irregular room shapes, may also be flagged for manual intervention to capture details that the AI might overlook. If the input document has incomplete or low-quality data, such as faded lines or missing annotations, the system may prompt for manual assistance to clarify uncertain areas. This selective use of manual detection may be understood to ensure high precision and reliability across various document types and project disciplines. In step 120, if manual object detection is required, a user may make adjustments by inputting data to refine object boundaries, confirm classifications, and correct dimensions. Users may adjust boundaries by dragging or resizing bounding boxes, entering specific measurements, or modifying dimensions where the AI's initial detection might be imprecise. For example, if a wall's length is inaccurately marked, the user may adjust it to align with the actual dimensions. Manual input may also include labeling objects to ensure correct classification, especially for elements that may be challenging for AI to differentiate, such as walls versus structural columns, and adding details like room names or materials. These adjustments may, in some embodiments, be made using input devices such as a mouse, keyboard, or touchscreen, allowing for precise control in resizing and boundary manipulation. In step 122 a combined list of detected objects may be made. If no object detection is required to process may skip to step 124, in step 124 the detected object list may be displayed, for example in a table format. In a next step 126 it may be determined whether the price and count needs to be modified. If the price and/or count needs to be modified then in a next step 128 an updated list may be made based off the modified price and count. If the price and count is not modified the process may skip to step 130, in step 130 an estimated cost based on the price and count may be stored in a database.

In a next step 132 it may be determined whether length detection should be run, if length detection should be run a length detection process may be started, if no length detection is run then in a next step 134 the estimated cost may be displayed, for example on a GUI to a user. In a next step 136 it may be determined if the estimated cost information may be exported to an output file, for example a CSV file. If the estimated cost information is exported in step 138 the data may be fetched from storage and exported, if no exportation is necessary step 138 may be skipped, in step 140 the process may be exited and the program ended in step 142.

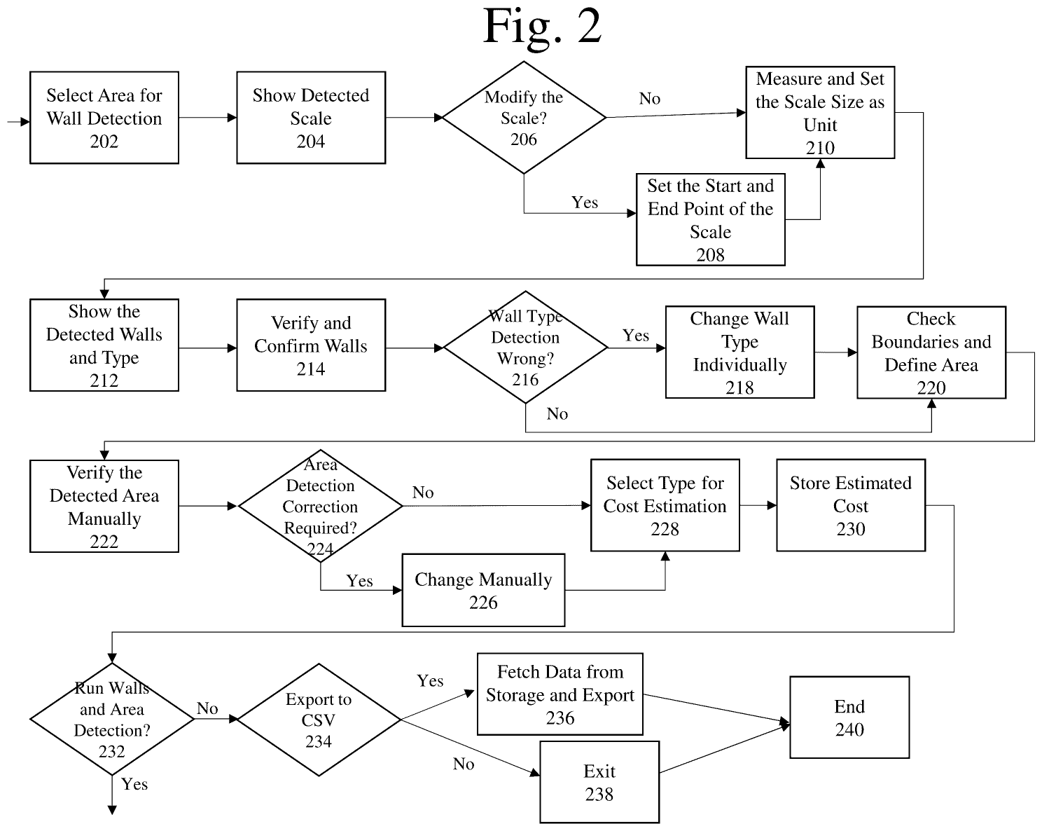

Referring to FIG. 2 a length detection process 200 according to an exemplary embodiment may be shown and described. It may be understood the length detection process 200 may be a subprocess initiated during another process, for example by step 132 in the input document analysis process 100, or may be a fully separate process. In a first step 202 an area may be selected for wall detection, which may be done, for example, manually by a user using a drawing tool to specify an area of interest. In a next step 204 a detected scale may be shown, which may be determined, for example by referencing known dimensions provided within the input document's legends. If the document includes a pre-defined scale bar or specified measurements, the system can automatically detect these references to establish an initial scale. The outer bounds of the scale are defined by selecting two points with a known distance between them, either detected by the AI from the document or manually specified by the user. In cases where the input document lacks explicit scale references, the user can manually calibrate the scale by selecting two points and entering the real-world distance between them. This process ensures that all measurements within the selected area reflect accurate, real-world values. The units (e.g., feet, meters) and intervals are either inferred from the document's metadata or input by the user, depending on the project's specific requirements. Once calibrated, the system applies this scale consistently across all detected elements within the area of interest (a specific page area, page or page range), enabling precise measurements for detected elements and subsequent cost estimation processes. In a next step 206 it may be determined whether the scale needs to be modified. If the scale needs to modified in a next step 208 the start and end point of the scale may set. If the scale does not need to be modified step 208 may be skipped, in a next step 210 the scale size may be measured and set.

In a next step 212 detected walls and wall types may be shown, and the walls may be verified and confirmed in step 214. In a next step 216 wall type detection may be initially performed by the system, which may identify different wall types based on visual characteristics such as hatching, shading, and/or line thickness. The AI may analyze these patterns to classify wall segments, associating each with a corresponding wall type (e.g., hatched or unhatched sections). However, in some cases, due to potential variations in document quality or non-standard symbols, user verification may be necessary. In these embodiments the user may verify each detected wall type to confirm its accuracy and, if adjustments are required, om step 218 may use, for example, a dropdown menu to select or reassign wall types (e.g., load bearing, partition, exterior wall). In some embodiments this combination of automated detection followed by user confirmation may ensure that each wall segment is correctly classified, enhancing the reliability of the system's cost estimation and architectural analysis. If no correction is required step 218 may be skipped and in step 220 boundaries created by the walls may be checked and an interior area may be defined based on the wall boundaries. In a next step 222 the detected area may be manually verified and the need for area detection correction may be checked in step 224. If area detection correction is required the detected area may be manually adjusted in step 226, if no correction is required step 226 may be skipped. In a next step 228 a cost estimation type may be selected based on the identified wall types. Each type may correspond to a specific set of cost parameters. For example, walls designated as load bearing may incur higher material and labor costs due to structural requirements, while partition walls might involve lower costs. Additionally, exterior walls may typically include costs for insulation, weatherproofing, and finishing, which may differ from the simpler finishing materials used for interior walls. Each wall type may be linked to a unique material, installation, and finishing costs, drawing from databases like the RS Means Cost Books. This approach may be understood to allow the system to provide precise, context-specific cost estimations. Once the cost estimation type is selected, the system may calculate the total estimated cost for the area and stores it in a database for further use in project budgeting or reporting. In step 230 the estimated cost may then be stored, for example in a database.

In a next step 232 it may be determined whether walls and area detection may be run, if walls and area detection may be run a walls and area detection process may be started, if no walls and area detection is run then in a next step 234 the length detection information may be exported to an output file, for example a CSV file. If the length detection information is exported in step 236 the data may be fetched from storage and exported, if no exportation is necessary step 236 may be skipped, in step 238 the process may be exited and the program ended in step 240.

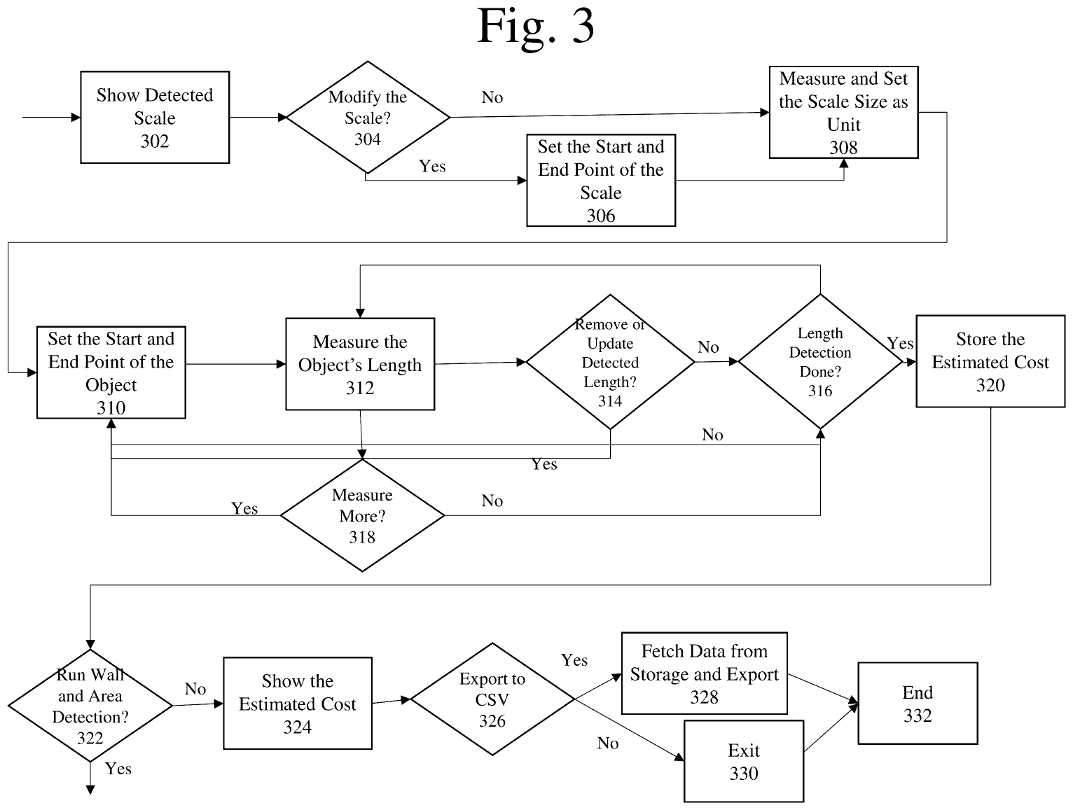

Referring to FIG. 3 a walls and area detection process 300 according to an exemplary embodiment may be shown and described. It may be understood the walls and area detection process 300 may be a subprocess initiated during another process, for example by step 232 in the length detection process 200, or may be a fully separate process. In a first step 302 a detected scale may be shown. In a next step 304 it may be determined whether the scale needs to be modified. If the scale needs to modified in a next step 306 the start and end point of the scale may set. If the scale does not need to be modified step 306 may be skipped, in a next step 308 the scale size may be measured and set. In a next step 310 a start point and an end point of an object be set, and in step 312 the object's length may be measured. In step 314 it may be determined whether the detected length should be updated or removed or if measuring of additional objects is needed at step 318. The criterion for determining whether the detected length should be updated or removed in step 314 may initially be software generated. The system may automatically assess the accuracy of the detected length based on the scale and object boundaries. If the software identifies discrepancies or areas where precision may be improved, it may flag those lengths for review. The user may then review the flagged lengths and provide confirmation or make adjustment as needed, which may be understood to ensure that the final measurement aligns with the actual dimensions and project requirements. If removal or updating is required the process may return to step 310, otherwise in step 316 it may be determined whether length detection has been completed. If length detection is not completed the process may return to step 310, if length detection is completed then at step 320 estimated cost may be stored. In step 322 it may be determined if an Optical Content Recognition (OCR) process may be run, if not then in step 324 the estimated cost may be displayed, for example to a user through a GUI. In a next step 326 the walls and area detection information may be exported to an output file, for example a CSV file. If the walls and area detection information is exported in step 326 the data may be fetched from storage and exported, if no exportation is necessary step 328 may be skipped, in step 330 the process may be exited and the program ended in step 332.

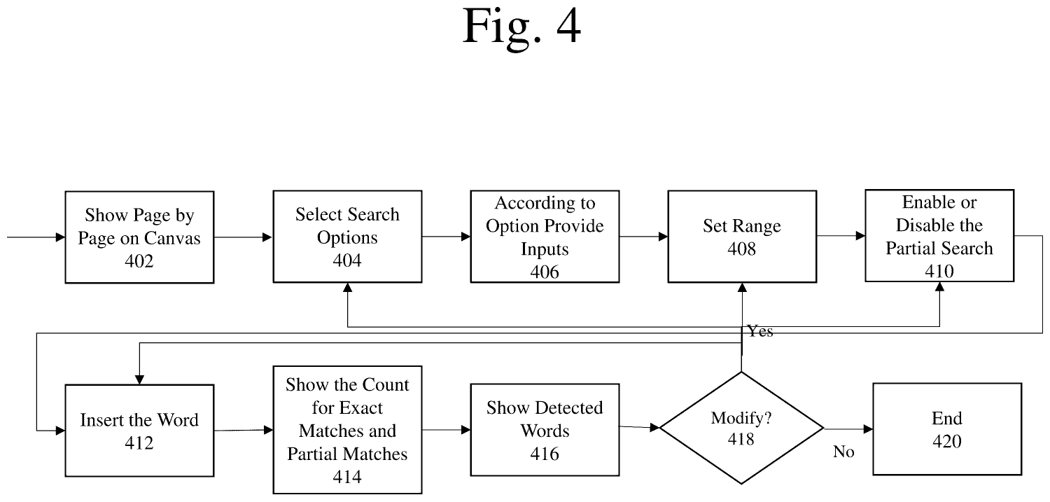

Referring to FIG. 4 an OCR process 400 according to an exemplary embodiment may be shown and described. It may be understood the OCR process 300 may be a subprocess initiated during another process, for example by step 322 in the walls and area detection process 300. In a first step 402 one or more pages may be shown page by page on a canvas, e.g. a computer screen. Each page may be, for example, a page of an annotated floorplan created by the processes described above. In a next step 404 a user may select one or more search options, and in step 406 may select one or more inputs based on the selected options. In a next step 408 the user may further set a range, e.g. a page range, for the OCR to run. In some embodiments a user may enable or disable partial search in step 410. According to an exemplary embodiment a partial match feature may allow for detection of words that share a signification portion of letters in the correct sequence, even if they are not exact matches. In step 412 the user may input a word for searching, and in step 414 the count for exact matches may be shown. If partial searches were enabled partial matches count may further be shown in step 414. In step 416 the detected words may further be shown. In step 418 the user may be given the option to modify the search, if the user selects to modify the search the process may return to step 408, in no modification is selected the process may end at step 420.

In some embodiments AI may be used to flag potential compliance code issues, for example noncompliance with one or more codes. In some embodiments the AI may further generate and suggest one or more design modifications in order to bring the floorplan within compliance with the one or more codes. As an example, a code may require that a bathroom or other room has a minimum square footage, and a given floorplan may have an indicated room that is below the given code. The AI may then suggest modifications to the walls or other structures that would enable the bathroom or other room to then meet the minimum square footage requirement. According to an exemplary embodiment, when proposing modifications to ensure code compliance the AI may consider a plurality of factors to balance practicality and adherence to relevant regulations such as the unified facilities criteria or local building codes. The factors may include, but are not limited to, cost efficiency, structural integrity, accessibility requirements such as ADA compliance, and aesthetic consistency.

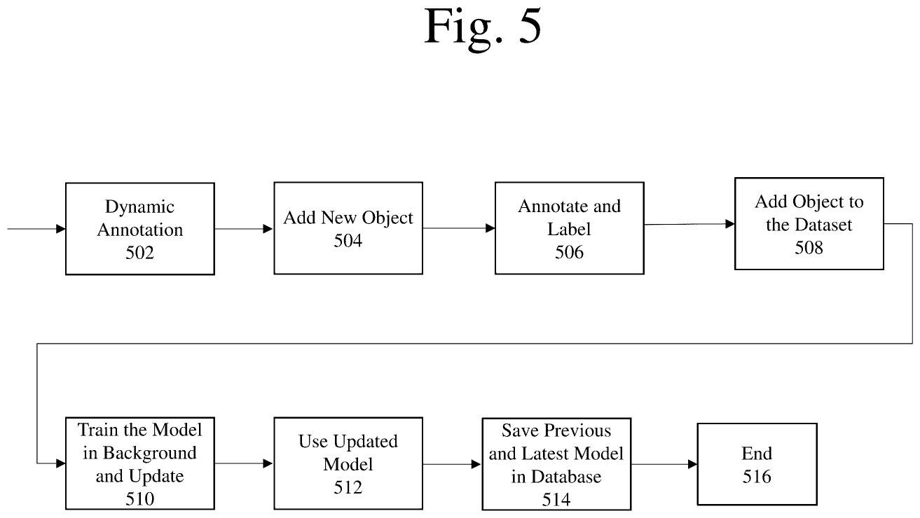

Referring to FIG. 5 a dynamic annotation process 500 according to an exemplary embodiment may be shown and described. In step 502 the Dynamic annotation process may be initiated and one or more new objects may be added in step 504. In a next step 506 each of the one or more objects may be annotated and labeled. For example, each object may be annotated with specific information relevant to its function and position within the drawing. Aspects of the annotation may include the object's type (e.g., wall, window, door) and its exact location in the drawing, which may be understood to ensure precise identification. Additional information, such as dimensions, material specifications, or unique identifiers, may also be included to provide context for each object. This detailed annotation allows for accurate categorization and integration of the object within the overall blueprint, supporting tasks like measurement, cost estimation, and compliance verification. In a next step 508 the one or more labeled and annotated objects may be added to a dataset in a database. In a next step 510 an artificial intelligence and/or machine learning model may be trained using the dataset with the labeled and annotated objects, and the updated model may be used in step 512. In a next step 514 the updated model and any previous versions of the model may be saved in the database. In a final step 516 the process may be ended.

According to an exemplary embodiment the AI utilized by any of the processes described may be a comprehensive system combining Convolutional Neural Networks (CNNs), Recurrent Neural Networks (RNNs) or Long Short-Term Memory (LSTM) networks, rule-based algorithms, and Natural Language Processing (NLP) techniques to handle various aspects of architectural analysis. CNNs may be employed for accurate object detection and classification, identifying structural elements such as walls, doors, and windows by analyzing spatial patterns within architectural drawings. RNNs or LSTMs may add the ability to process sequential data, capturing relational information, such as sequences and logical flow across multi-page documents. Rule-based algorithms may enhance the model by enforcing compliance with building codes and design standards, like minimum dimensions or accessibility requirements. For the OCR component, NLP techniques may interpret extracted text, recognizing names, material specifications, and annotations, and handle domain-specific terms and abbreviations to enrich the text analysis. Training the model on a diverse dataset of labeled and annotated objects may enable it to learn and adapt to the unique aspects of documentation, ensuring high accuracy in detection, measurement, and compliance tasks. With each update, previous model versions may be stored in a database to track improvements and maintain consistent performance, which may be understood to allow for a multi-faceted model with both reliability and adaptability across a range of disciplines and cost estimation functions.

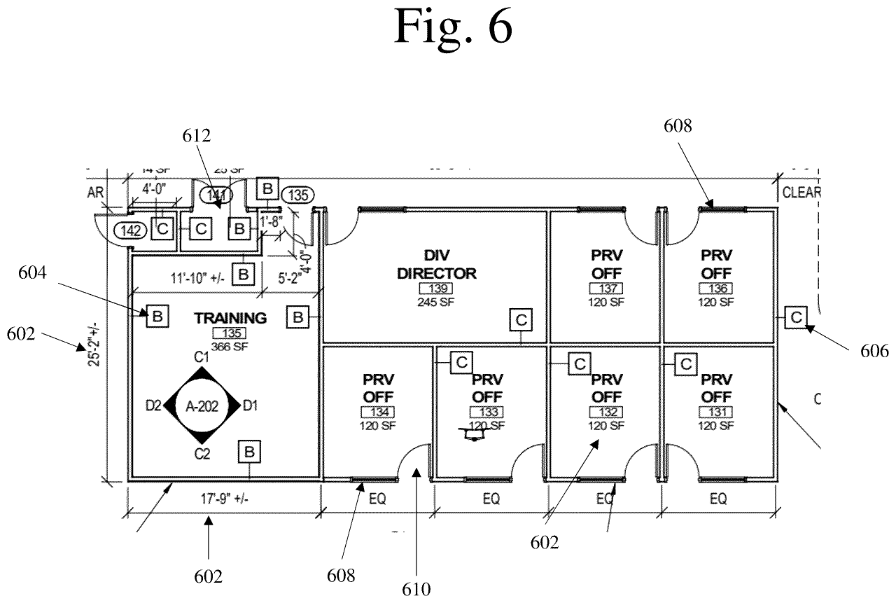

Referring generally to FIG. 6, an exemplary floor plan 600 may be shown and described. The exemplary floor plan may be generated by, for example, one or more of the processes described above, and may contain one or more data point annotations as determined by the AI, for example square footage annotations 602. Additional annotations may include B type walls 604, C type walls 606, glass partitions 608, single doorways 610, and double doorways 612.

It may be understood that the above processes may utilize the described AI and/or ML system in real-time, and adjustments made to the defined areas, scales, or costs may be made and updated in real-time to the user.

In some embodiments a data frame operation system may be used to organize, manipulate, and/or analyze structured data in a tabular format, similar to a spreadsheet or database table. The Data Frame system may allow one or more users to perform a variety of operations on data, such as filtering rows, sorting by specific columns, and/or grouping data based on categories. The one or more users may perform analysis by, for example, calculating summary statistics, creating new columns with derived values, and/or merging multiple data tables. Additionally, the Data Frame system may support data cleaning tasks, which may enable users to handle missing values, correct data types, and/or standardize formats. With built-in functions for handling large datasets efficiently, the Data Frame operation system may further provide an environment for transforming raw data into actionable insights, allowing for tasks like reporting, visualization, and data export in multiple formats.

The foregoing description and accompanying figures illustrate the principles, preferred embodiments and modes of operation of the invention. However, the invention should not be construed as being limited to the particular embodiments discussed above. Additional variations of the embodiments discussed above will be appreciated by those skilled in the art.

Therefore, the above-described embodiments should be regarded as illustrative rather than restrictive. Accordingly, it should be appreciated that variations to those embodiments can be made by those skilled in the art without departing from the scope of the invention as defined by the following claims.

What is claimed is:

1. A method for planning and cost engineering using an artificial intelligence comprising:
receiving one or more input documents, the input documents including at least architectural design information;
converting the input documents into an image file;
automatically setting a scale unit based on at least one known measurement of the input documents;
verifying the scale unit;
automatically measuring one or more lengths and one or more areas of the image file based on the architectural design information; and
automatically labeling the one or more measured lengths and one or more measured areas on the image file to generate a labeled image.

2. The method of claim 1, further comprising;
automatically detecting one or more drawing elements of the image file;
automatically classifying each of the one or more drawing elements into one or more classifications;
linking each of the one or more classifications to at least a material;
calculating, based on the linked material, a cost estimate for each of the one or more drawing elements.

3. The method of claim 2, further comprising;
receiving one or more user provided adjustments for the one or more lengths and/or areas of the image file;
automatically recalculating, based on the user provided adjustments, the cost estimates for each of the one or more drawing elements.

4. The method of claim 2, further comprising;
automatically detecting one or more line segments of the image file.

5. The method of claim 3, further comprising;
modifying the one or more line segments based off a user-provided input; and
automatically adjusting, by the AI and in substantially real-time, the cost estimates for each of the one or more drawing elements based on the modified line segments.

6. The method of claim 2, wherein the AI includes at least a Convolutional Neural Network (CNN), a Recurrent Neural Network (RNN), and a Long Short-Term Memory network (LSTM).

7. The method of claim 3, wherein the AI incorporates at least one user provided annotation of a new element to improve future analysis.

8. The method of claim 2, further comprising:
utilizing Object Content Recognition (OCR) to extract text from the input documents;
performing a compliance check on the input document against at least one code;
automatically flagging at least one conflict against the compliance code.

9. The method of claim 8, further comprising;
automatically suggesting at least one design modification to resolve the at least one conflict against the compliance code.

10. The method of claim 1, further comprising;
automatically exporting the labeled image as a CSV file to a project management software.

11. A system for planning and cost engineering using an artificial intelligence comprising;
an artificial intelligence (AI) model;
a non-transitory computer-readable storage medium storing computer executable instructions; and
a processor configured to execute the computer executable instructions to perform the steps of:
receiving one or more input documents, the input documents including at least architectural design information;
converting the input documents into an image file;
automatically setting a scale unit based on at least one known measurement of the input documents;
verifying the scale unit;
automatically measuring one or more lengths and one or more areas of the image file based on the architectural design information; and
automatically labeling the one or more measured lengths and one or more measured areas on the image file to generate a labeled image.

12. The system of claim 11, the instructions further comprising:
automatically detecting one or more drawing elements of the image file;
automatically classifying each of the one or more drawing elements into one or more classifications;
linking each of the one or more classifications to at least a material;
calculating, based on the linked material, a cost estimate for each of the one or more drawing elements.

13. The system of claim 12, further comprising at least a user input method configured to receive one or more user provided adjustments for the one or more lengths and/or areas of the image file;
wherein the cost estimate is automatically re-calculated based on the one or more user provided adjustments.

14. The system of claim 13, wherein the user input method is one of a mouse, a keyboard, or a touchscreen device.

15. The system of claim 13, wherein the user input method is configured to allow a user to manually resize or adjust one or more boundaries used to calculate the one or more lengths and/or areas of the image file.

16. The system of claim 11, wherein the AI model further comprises at least a Convolutional Neural Network (CNN), a Recurrent Neural Network (RNN), and a Long Short-Term Memory network (LSTM).

17. The system of claim 16, wherein the AI model further includes Natural Language Processing (NLP) techniques; and
wherein the instructions further comprise;
utilizing Object Content Recognition (OCR) to extract text from the input documents;
performing a compliance check on the input document against at least one code; and
automatically flagging at least one conflict against the compliance code.

18. The system of claim 17, wherein the AI model further automatically suggests at least one design modification to resolve the at least one conflict against the compliance code.

19. The system of claim 12, wherein the cost estimations are further based on at least a cost data library, and further include at least labor, taxes, and shipping.

20. The system of claim 19, wherein the cost estimates are further based off at least one user provided cost.
